(19) United States
(12) Patent Application Publication
(10) Pub. No.: US 2012/0111619 A1
(43) Pub. Date: May 10, 2012

(54) CIRCUIT SUBSTRATE AND MANUFACTURING METHOD OF CIRCUIT SUBSTRATE

(75) Inventor: Hirohisa Amago, Kanagawa (JP)

(73) Assignee: SONY CORPORATION, Tokyo (JP)

(21) Appl. No.: 13/286,783

(22) Filed: Nov. 1, 2011

(30) Foreign Application Priority Data
Nov. 9, 2010 (JP) 2010-251268

(51) Int. Cl. H05K 1/02; H05K 3/10

(52) U.S. Cl. 174/258; 29/846

(57) ABSTRACT

A circuit substrate includes a substrate having a wiring formation surface formed in a planar shape; a primer resin layer formed on the wiring formation surface of the substrate and having a predetermined adhesive force with respect to the substrate; and a wiring layer formed on the primer resin layer, wherein the wiring layer is formed by removing a portion of the conductive ink, which contacts the wiring formation surface of the substrate coated so as to cover the primer resin layer by a removing unit, in which the adhesive force of a conductive ink with respect to the substrate is smaller than the adhesive force of the primer resin layer with respect to the substrate.

### BACKGROUND

The present disclosure relates to a technical field regarding a circuit substrate and a manufacturing method of the circuit substrate. Specifically, the disclosure relates to a technical field to manufacture a circuit substrate having a very fine wiring layer in a simple process by removing a portion of the conductive ink, which contacts the substrate, coated so as to cover the primer resin layers that are formed on the substrate.

In various types of electronic devices, a circuit substrate where predetermined conductive patterns (wiring layers) are formed is arranged.

The circuit substrate is manufactured for example, by a photolithography method. The manufacturing of the circuit substrate according to the photolithography method is performed wherein light exposure is performed using a photomask or the like after a photoresist that is a plating resist is coated on a substrate (a glass substrate) that is formed with a seed layer for conductivity according to a sputtering or the like, sequentially developing, copper plating and exfoliating of the photoresist are performed, and the seed layer is etched.

However, the manufacturing method of the circuit substrate according to the photolithography method has a necessary of performing various processes such as a plating process on the substrate, a forming process of the photoresist layer, a light exposure process, a developing process and the like. The manufacturing method may have problems wherein the manufacturing method is complicated and the manufacturing costs increase.

In addition, there is an environmental problem in which waste fluids generated in large amounts in the developing process and the plating process are harmful and a predetermined process is necessary to be performed in order to dispose of the waste fluid.

Meanwhile, a method is reviewed in which a conductive pattern is formed on a glass substrate by printing using a screen or the like and a circuit substrate is manufactured, however the method has problems in which desirable positional accuracy of the conductive pattern that is formed is difficult to be secured and the method may not be applied to the manufacturing of the circuit substrate that necessitates forming a very fine conductive pattern.

Accordingly, as a manufacturing method of a circuit substrate in which a very fine conductive pattern may be formed and the problem of the waste fluid disposal may not occur, a manufacturing method using a photocatalyst (for example, see Japanese Unexamined Patent Application Publication No. 2004-87976 and Japanese Unexamined Patent Application Publication No. 2009-81441) is suggested.

In the manufacturing method using the photocatalyst, a material of which the wettability is changed by an action of the photocatalyst is formed on a substrate by a coating, an energy irradiation is performed so that a pattern is formed, and then conductive ink is coated so that a very fine conductive pattern is formed.

### SUMMARY

However, in the manufacturing method that uses the photocatalyst disclosed in Japanese Unexamined Patent Application Publication No. 2004-87976 and Japanese Unexamined Patent Application Publication No. 2009-81441, there are problems in which a process of a lithography method such as a developing process or an exposure process for a photoreaction is necessary, the circuit substrate may not be manufactured in a simple process, the manufacturing time is long and the manufacturing costs are increased.

Thus, in the circuit substrate and the manufacturing method of the circuit substrate of the present disclosure, it is desirable that the circuit substrate be manufactured in a simple process, the manufacturing time be shortened and the manufacturing costs be decreased.

According to an embodiment of the present disclosure, there is provided a circuit substrate including: a substrate having a wiring formation surface formed in a planar shape; a primer resin layer formed on the wiring formation surface of the substrate and having a predetermined adhesive force with respect to the substrate; and a wiring layer formed on the primer resin layer, wherein the wiring layer is formed by removing a portion of the conductive ink which contacts the wiring formation surface of the substrate coated so as to cover the primer resin layer by a removing unit, in which the adhesive force of the conductive ink with respect to the substrate is smaller than the adhesive force of the primer resin layer with respect to the substrate.

Accordingly, the removing unit removes the extra portion of the conductive ink so that the wiring layer is formed.

In the circuit substrate according to the embodiment of the present disclosure, it is desirable that as the removing unit, an adhesive roll that has an adhesive on the outer peripheral surface thereof and is rotatable in the shaft-rotation direction be used, and the adhesive roll be rotated and the adhesive roll on the conductive ink so that a portion of the conductive ink which contacts the wiring formation surface of the substrate is removed.

The adhesive roll is rotated and the adhesive rolls on the conductive ink so that a portion of the conductive ink, which contacts the wiring formation surface of the substrate, is removed so that the extra portion of the conductive ink is removed by the rotation of the adhesive roll and then the wiring layer is formed.

In the above-described circuit substrate, it is desirable that the conductive ink that covers the primer layer be coated so as to contact the entire surface of the wiring formation surface of the substrate.

In the circuit substrate according to the embodiment of the present disclosure, the conductive ink that covers the primer resin layer is coated so as to contact the entire surface of the wiring formation surface of the substrate so that a plate or a mechanism for coating the conductive ink in order to cover the primer layer respectively is not necessary.

In the above-described circuit substrate, it is desirable that coloring be performed at the primer resin layer.

In the circuit substrate according to the embodiment of the present disclosure, coloring of the primer resin layer is performed so that an inspection of the forming state of the primer resin layer with respect to the substrate is easily performed.

According to another embodiment of the present disclosure, there is provided a manufacturing method of a circuit substrate including: forming a primer resin layer having a predetermined adhesive force with respect to a substrate on a wiring formation surface of the substrate that has the wiring formation surface formed in a planar shape; coating conductive ink so as to cover the primer resin layer, in which the adhesive force of the conductive ink with respect to the substrate is smaller than the adhesive force of the primer resin layer with respect to the substrate; and removing a portion of the conductive ink which contacts the wiring formation surface of the substrate by a removing unit to form the wiring layer.

Accordingly, the removing unit removes the extra portion of the conductive ink so that the wiring layer is formed.

In the manufacturing method of a circuit substrate according to the embodiment of the present disclosure, it is desirable that as the removing unit, an adhesive roll that has an adhesive on the outer peripheral surface thereof and is rotatable in a shaft-rotation direction be used, and the adhesive roll be rotated and the adhesive roll on the conductive ink so that a portion of the conductive ink which contacts the wiring formation surface of the substrate is removed.

The adhesive roll is rotated and the adhesive rolls on the conductive ink so that a portion of the conductive ink, which contacts the wiring formation surface of the substrate, is removed so that the extra portion of the conductive ink is removed by the rotation of the adhesive roll and then the wiring layer is formed.

In the above-described manufacturing method of a circuit substrate, it is desirable that the conductive ink that covers the primer layers be coated so as to contact the entire surface of the wiring formation surface of the substrate.

In the manufacturing method of a circuit substrate according to the embodiment of the present disclosure, the conductive ink that covers the primer resin layer is coated so as to contact the entire surface of the wiring formation surface of the substrate so that a plate or a mechanism for coating the conductive ink in order to cover the primer layer respectively is not necessary.

In the manufacturing method of a circuit substrate according to the embodiment of the present disclosure, it is desirable that coloring of the primer resin layers be performed.

Coloring of the primer resin layer is performed so that an inspection of the forming state of the primer resin layer with respect to the substrate is easily performed.

The circuit substrate of the embodiment of the present disclosure includes a substrate having a wiring formation surface formed in a planar shape; a primer resin layer formed on the wiring formation surface of the substrate and having a predetermined adhesive force with respect to the substrate; and a wiring layer formed on the primer resin layer, wherein the wiring layer is formed by removing a portion of the conductive ink, which contacts the wiring formation surface of the substrate, coated so as to cover the primer resin layers by a removing unit, in which the adhesive force of the conductive ink with respect to the substrate is smaller than the adhesive force of the primer resin layer with respect to the substrate.

Accordingly, the circuit substrate may be manufactured in a simple process, the manufacturing time may be shortened and the manufacturing costs may be decreased.

In the circuit substrate according the embodiment of the present disclosure, as the removing unit, an adhesive roll that has an adhesive on the outer peripheral surface thereof and is rotatable in a shaft-rotation direction is used, and wherein the adhesive roll is rotated and the adhesive rolls on the conductive ink so that a portion of the conductive ink which contacts the wiring formation surface of the substrate is removed.

Accordingly, the extra conductive ink as the wiring layer may be simply and reliably removed.

In the circuit substrate according the embodiment of the present disclosure, the conductive ink that covers the primer resin layers is coated so as to contact the entire surface of the wiring formation surface of the substrate.

Accordingly, the plate or the mechanism for coating the conductive ink in order to cover the primer resin layer respectively is not necessary so that, at that rate, the manufacturing costs may be decreased.

In the circuit substrate according the embodiment of the present disclosure, coloring of the primer resin layer is performed.

Accordingly, the inspection of the forming state of the primer layer with respect to the substrate is easily performed and the positional accuracy of the wiring layer may be enhanced.

The manufacturing method of a circuit substrate of another embodiment of the present disclosure includes forming a primer resin layer having a predetermined adhesive force with respect to a substrate on a wiring formation surface of the substrate that has the wiring formation surface formed in a planar shape; coating conductive ink so as to cover the primer resin layer, in which the adhesive force of the conductive ink with respect to the substrate is smaller than the adhesive force of the primer resin layer with respect to the substrate; and removing a portion of the conductive ink which contacts the wiring formation surface of the substrate by a removing unit so that the wiring layers are formed.

Accordingly, the circuit substrate may be manufactured in a simple process, the manufacturing time may be shortened and the manufacturing costs may be decreased.

In the manufacturing method of a circuit substrate according the embodiment of the present disclosure, as the removing unit, an adhesive roll that has an adhesive on the outer peripheral surface thereof and is rotatable in a shaft-rotation direction is used, and wherein the adhesive roll is rotated and the adhesive rolls on the conductive ink so that a portion of the conductive ink which contacts the wiring formation surface of the substrate is removed.

Accordingly, the extra conductive ink as the wiring layer may be simply and reliably removed.

In the manufacturing method of a circuit substrate according the embodiment of the present disclosure, the conductive ink that covers the primer resin layers are coated so as to contact the entire surface of the wiring formation surface of the substrate.

Accordingly, the plate or the mechanism for coating the conductive ink in order to cover the primer resin layer respectively is not necessary so that, at that rate, the manufacturing costs may be decreased.

In the manufacturing method of a circuit substrate according the embodiment of the present disclosure, coloring of the primer resin layer is performed.

Accordingly, the inspection of the forming state of the primer layer with respect to the substrate is easily performed and the positional accuracy of the wiring layer may be enhanced.

### BRIEF DESCRIPTION OF THE DRAWINGS

FIG. 1 is an enlarged cross-sectional view schematically illustrating a circuit substrate and illustrating an embodiment of a manufacturing method of the circuit substrate of the present disclosure with FIGS. 2 to 10;

FIG. 2 is a flowchart illustrating the manufacturing method of the circuit substrate;

FIG. 3 is a cross-sectional view schematically illustrating a forming state of a primer resin layer to the substrate and illustrating each state of the manufacturing method of the circuit substrate of the present disclosure with FIGS. 4 to 10;

FIG. 4 is a cross-sectional view schematically illustrating a drying state of a primer resin layer;

FIG. 5 is a cross-sectional view schematically illustrating a state where conductive ink is coated in order to cover a primer resin layer;

FIG. 6 is a cross-sectional view schematically illustrating a state where firing of the conductive ink is performed;

FIG. 7 is a cross-sectional view schematically illustrating a state where an adhesive roll contacts the conductive ink;

FIG. 8 is a cross-sectional view schematically illustrating a state where the adhesive roll rotates and extra conductive ink is removed;

FIG. 9 is a cross-sectional view schematically illustrating a state where extra conductive ink is removed and the circuit substrate is manufactured; and

FIG. 10 is a cross-sectional view schematically illustrating a state where conductive ink is coated in order to cover a primer resin layer and the entirety of the substrate.

### DETAILED DESCRIPTION OF EMBODIMENTS

Below, embodiments of a circuit substrate and a manufacturing method of the circuit substrate are described with reference to the attached drawings.

The printing forms a fine conductive pattern (a wiring layer) so that the circuit substrate and the manufacturing method of the circuit substrate of the disclosure are capable of decreasing the environmental load or promoting lower costs. Thus the best embodiment described below is applied to the circuit substrate and the manufacturing method of the circuit substrate that are manufactured by printable electronics technology.

The circuit substrate that is manufactured by the printable electronics technique is applied for example, to a flat panel display or the like such as a liquid crystal display, a plasma display, or an organic electro-luminescent display.

In the description below, for example, a direction is illustrated in a state where the substrate that functions as a printed material where the wiring layer is formed is arranged in the up and down direction, however the embodiment of the disclosure is not limited to the direction.

Configuration of Circuit Substrate

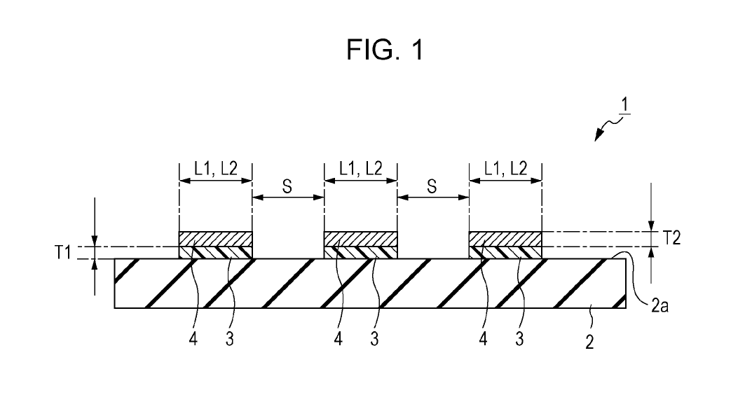

As shown in FIG. 1, a circuit substrate 1 has a planar-shaped substrate 2 that is functioned as the printed material, primer layers 3,3, . . . that are formed on the substrate 2 and the wiring layers 4,4, . . . that are formed on the primer layers 3,3, . . . respectively, and the wiring layers 4,4, . . . function as conductive patterns.

The substrate 2 has a wiring formation surface 2a that is a surface where the wiring layers 4,4, . . . are formed and for example, if the wiring layers 4,4, . . . are formed at both surfaces thereof, the both surfaces are the wiring formation surfaces 2a and 2a. A material having an insulation property for example, a glass such as an alkali-free glass forms the substrate 2. In addition, a resin material such as polyethyleneterephthalate, polyimide or the like may be used as the substrate 2.

The primer layers 3,3, . . . have for example, a thickness T1 of 0.2 μm to 0.3 μm, and a width L1 of 8 μm. A distance S between the primer layers 3,3, . . . is for example, 8 μm. As the primer layers 3,3, . . . , for example, solvent-type adhesives such as an epoxy type, a phenol type, a polyester type are used and the primer layers 3,3, . . . have high adhesive force with respect to the substrate 2.

The wiring layers 4,4, . . . have for example, 3 μm of a thickness T2 and 8 μm of a width L2. As the wiring layers 4,4, . . . , for example, a silver nano-ink is used. The wiring layers 4,4, . . . have a high adhesive force with respect to the primer layers 3,3, . . . however, have a weak adhesive force with respect to the substrate 2. The adhesive force of the wiring layers 4,4, . . . with respect to the substrate 2 is considerably smaller than the adhesive force of the primer layers 3,3, . . . with respect to the substrate 2.

In addition, the material of the wiring layers 4,4, . . . may use for example, gold, copper, nickel, tin, lead or the like.

As described above, the wiring layer 4 has 3 μm of the thickness and 8 μm of the width. The aspect ratio is as high as 0.3 or more and the improvement of the reliability regarding the conductivity is promoted.

Manufacturing Method of Circuit Substrate

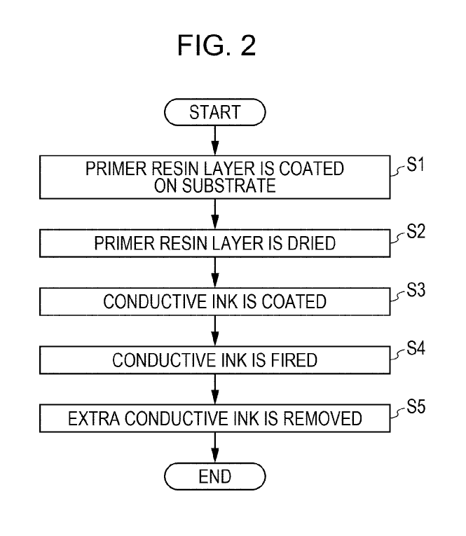

Description will be given below regarding the manufacturing method of the circuit substrate 1 (see FIGS. 2 to 10).

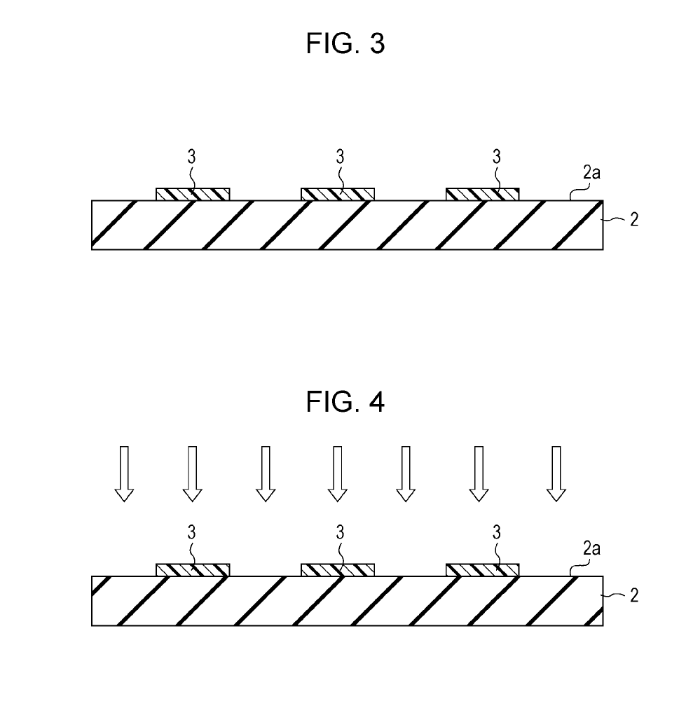

FIG. 2 is a flowchart illustrating each of processes of the manufacturing method of the circuit substrate 1. FIGS. 3 to 10 are configuration drawings illustrating the states of each process.

(S1) First of all, the substrate 2 is prepared and the primer layers 3,3, . . . are formed for example, by printing at a predetermined position on the wiring formation surface 2a of the substrate 2 in other words, at a position where the conductive pattern is formed (see FIG. 3). As a forming method (a printing method) of the primer layers 3,3, . . . with respect to the substrate 2 may use various methods such as a inkjet, a screen method using a screen plate, offset printing or a gravure printing using a engraved plate, a flexo printing using a relief plate.

(S2) Next, the primer layers 3,3, . . . that formed at the substrate 2 in process S1 are dried (see FIG. 4). An oven using hot air or far infrared rays, a drying furnace using a vacuum, a hot plate that heats the primer layers 3,3, . . . from a surface opposed to the wiring formation surface 2a, or the like perform the drying of the primer layers 3,3, . . . . The heating that uses the hot plate is performed, for example, for about 10 minutes at 100° C. The drying of the primer layers 3,3, . . . is performed by removing the solvent from the primer layers 3,3, . . . to a degree that inconvenience does not occur when the wiring layers 4,4, . . . that are formed on the primer layers 3,3, . . . are printed in the next process (S3).

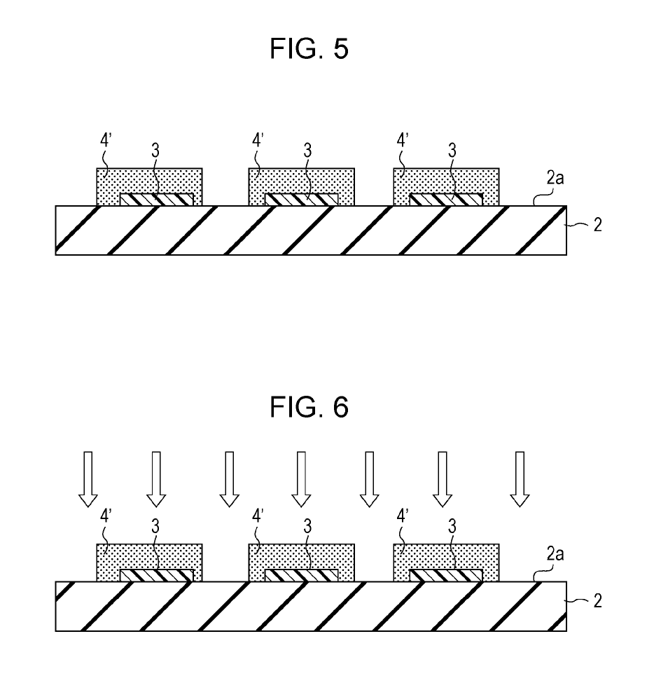

(S3) Next, conductive ink 4′, 4′, . . . coats the primer layers 3,3, . . . that are dried in the process S2 so as to cover the primer layers 3,3, . . . respectively (see FIG. 5). In other words, the conductive ink 4′, 4′, . . . covers the entirety of the primer layers 3,3, . . . respectively in the coated state and a portion of the conductive ink 4′, 4′, . . . is in a contacted state to the wiring formation surface 2a.

At this time, the width of the conductive ink 4′, 4′, . . . that is coated is for example, 12 μm and the distance between the conductive ink 4′, 4′, . . . is for example, 4 μm. As the conductive ink 4′, 4′, . . . a material is used in which a binder, a solvent and a dispersing agent of which the main components are a conductive polymer or a metal powder such as gold, silver, copper, nickel, tin and lead, are mixed, is blended and dispersed so as to be applied to various printing methods.

As the printing method of the conductive ink 4′, 4′, . . . for example, various printing methods may be used such as inkjet printing, screen printing using a screen plate, offset printing or gravure printing using engraved plate, the flexo printing using the relief plate.

In process S2, coloring of the primer layers 3,3, . . . is performed so that the forming state of the primer layers 3,3, . . . with respect to the substrate 2 is easily inspected. The inspection of the forming state of the primer layers 3,3, . . . with respect to the substrate 2 is performed so that the coating of the conductive ink 4′, 4′, . . . on the primer layers 3,3, . . . may be performed in a state where the primer layers 3,3, . . . are reliably formed at predetermined positions. Accordingly, the positional accuracy of the wiring layers 4, 4, . . . that are formed at a process after a process S4 may be improved.

(S4) In succession, a firing of the conductive ink 4′, 4′, . . . that coated in process S3 is performed (see FIG. 6). The firing of the conductive ink 4′, 4′, . . . is a process that develops the conductivity of the conductive ink 4′, 4′, . . . and the conductive ink 4′, 4′, . . . is hardened by a heating furnace using hot air or far infrared rays. The firing by the heating furnace is performed for about 60 minutes at 230° C.

The firing of the conductive ink 4′, 4′, . . . may be performed by using a laser or plasma.

The adhesion (adhesive force) of the conductive ink 4′ with respect to a primer layer 3 is extremely large and the adhesive force of the conductive ink 4′ with respect to the substrate 2 is much smaller than the adhesive force of the primer layer 3 with respect to the substrate 2.

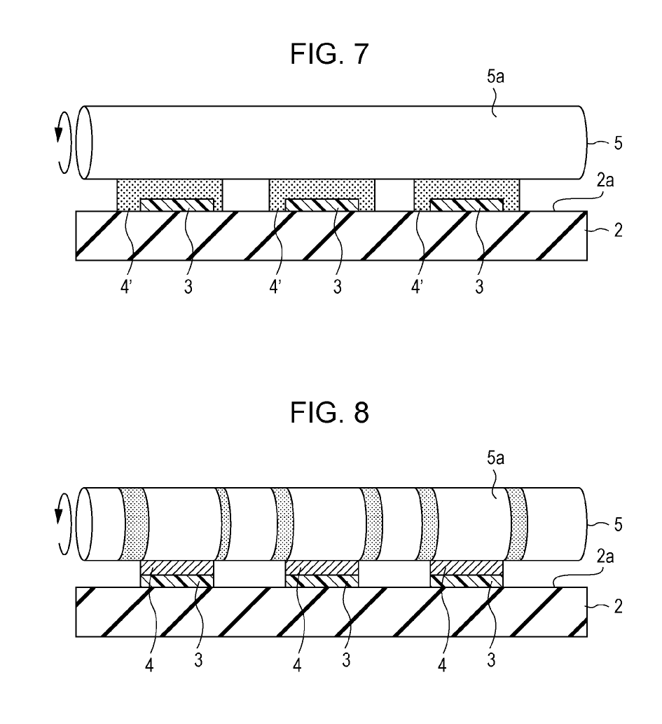

(S5) Lastly, a portion of the conductive ink 4′, 4′, . . . that is fired in the process S4 is removed (exfoliated) by a removing unit so that the wiring layers 4,4, . . . are formed (see FIGS. 7 to 9).

As the removing unit, for example, an adhesive roll 5 is used and adhesive 5a is attached on the outer peripheral surface of the adhesive roll 5 (see FIG. 7). As the adhesive 5a of the adhesive roll 5, for example, an acryl type adhesive material is used.

The adhesive roll 5 rotates in a shaft-rotation direction and the adhesive 5a rolls on the conductive ink 4′, 4′, . . . so that a portion of the conductive ink 4′, 4′, . . . is removed by the adhesive roll 5. At this time, since the adhesive force of the conductive ink 4′, 4′, . . . with respect to the substrate 2 is small, only a portion of the conductive ink 4′, 4′, . . . which contacts the wiring formation surface 2a of the substrate 2 is adhered to the adhesive 5a and then is exfoliated (see FIG. 8).

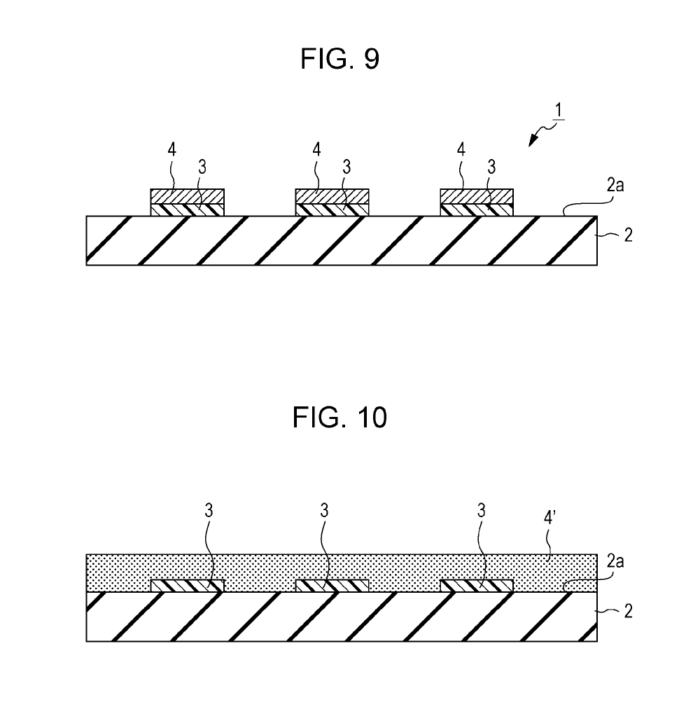

As described above, only a portion of the conductive ink 4′, 4′, . . . which contacts the wiring formation surface 2a of the substrate 2 is adhered to the adhesive 5a and removed by the adhesive roll 5 so that the wiring layers 4,4, . . . are formed on the primer layers 3,3, . . . respectively (see FIG. 9).

The wiring layers 4,4, . . . are formed on the primer layers 3,3, . . . respectively so that the circuit substrate 1 is manufactured.

In the above description, the adhesive roll 5 where the adhesive 5a is attached at the outer peripheral surface thereof is exemplified as the removing unit, however for example, as the removing unit, a structure may be used wherein an adhesive sheet where the adhesive is attached is pinched between the conductive ink 4′, 4′, . . . and a rotatable roll body, and the roll body is rotated so that the adhesive sheet is transported and then a portion of the conductive ink 4′, 4′, . . . is exfoliated.

In addition, the removing (exfoliating) of a portion of the conductive ink 4′, 4′, . . . may be also performed for example, according to fine powder of ceramics or water being ejected at high pressure with respect to the conductive ink 4′, 4′, . . . .

Furthermore, in process (S3), an example is illustrated, in which the conductive ink 4′, 4′, . . . is coated so as to cover the primer layers 3,3, . . . respectively, however the conductive ink 4′ may coat so as to cover the entire surface of the wiring formation surface 2a of the substrate 2 and the primer layers 3,3, . . . (see FIG. 10).

The conductive ink 4′, 4′, . . . is coated so as to cover the entire surface of the wiring formation surface 2a of the substrate 2 and the primer layers 3,3, . . . so that a plate or a mechanism for coating the conductive ink 4′, 4′, . . . to cover the primer layers 3,3, . . . may not be provided, meaning that the manufacturing costs may be decreased.

However, the conductive ink 4′, 4′, . . . is coated so as to cover the primer layers 3,3, . . . respectively so that the primer layers 3,3, . . . are covered respectively, the removing amount of the conductive ink 4′, 4′, . . . is small and the material costs may be decreased by decreasing the use of the conductive ink 4′, 4′, . . . .

### CONCLUSION

As described above, on the circuit substrate 1, the conductive ink 4′, 4′, . . . is coated so as to cover the primer layers 3,3, . . . and a portion of the conductive ink 4′, 4′, . . . which contacts the wiring formation surface 2a of the substrate 2 is exfoliated and removed by the adhesive roll 5 so that the wiring layers 4,4, . . . are formed.

Accordingly, the circuit substrate 1 may be manufactured in simple processes, the manufacturing time may be shortened and the manufacturing costs may be decreased.

In addition, as the removing unit, the adhesive roll 5 where the adhesive 5a is attached at the outer peripheral surface thereof is used so that the conductive ink 4′, 4′, . . . that is extra portion as the wiring layers 4,4, . . . may be removed simply and reliably.

Also, when the conductive ink is used and then very fine wiring layer is formed on the glass substrate by the printing, generally, existing problems are described below.

(1) It is difficult to form the wiring layer (the wiring layer having a thick film) having the high aspect ratio.

(2) The thickness of the wiring layer that is printed is thickened so that it is difficult to form the wiring layer with high positional accuracy according to the printing.

(3) The adhesive force between the conductive ink and the glass substrate is small. In this case, if the conductive ink contains resin having high adhesive force, the electric resistivity is increased and the function of the wiring layer is decreased.

With respect to the problems, as the above-described circuit substrate 1, the extra portion of the conductive ink 4′, 4′, . . . is removed and the wiring layers 4,4, . . . are formed so that advantages are present as described in below.

(1) The circuit substrate 1 having the high aspect ratio of the very fine wiring layers 4,4, . . . may be formed.

(2) The very fine wiring layers 4,4, . . . having a high adhesion (adhesive force) and a small resistance may be formed.

(3) The circuit substrate 1 having a small environmental load may be formed considering the environment.

(4) High positional accuracy of the primer layers 3,3, . . . is secured with respect to the substrate 2 so that the high positional accuracy of the wiring layers 4,4, . . . may be secured even though the conductive ink 4′, 4′, . . . is not coated in high positional accuracy.

(5) Since the very fine wiring layers 4,4, . . . may be formed with a simple method, the improvement of yield may be realized.

(6) Since the circuit substrate 1 where the high positional accuracy of the wiring layers 4,4, . . . is secured by the simple method may be manufactured, the productivity may be improved.

The detailed shape and structure of each of portions of the above-described best embodiment are only an example of embodiments when the disclosure is practiced and the technical range of the disclosure may not be interpreted by the embodiments.

The present disclosure contains subject matter related to that disclosed in Japanese Priority Patent Application JP 2010-251268 filed in the Japan Patent Office on Nov. 9, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A circuit substrate comprising:
a substrate having a wiring formation surface formed in a planar shape;
a primer resin layer formed on the wiring formation surface of the substrate and having a predetermined adhesive force with respect to the substrate; and
a wiring layer formed on the primer resin layer,
wherein the wiring layer is formed by removing a portion of the conductive ink, which contacts the wiring formation surface of the substrate, coated so as to cover the primer resin layer by a removing unit, in which an adhesive force of the conductive ink with respect to the substrate is smaller than an adhesive force of the primer resin layer with respect to the substrate.

2. The circuit substrate according to claim 1, wherein as the removing unit, an adhesive roll that has an adhesive on an outer peripheral surface thereof and is rotatable in a shaft-rotation direction is used, and
wherein the adhesive roll is rotated and the adhesive rolls on the conductive ink so that a portion of the conductive ink, which contacts the wiring formation surface of the substrate, is removed.

3. The circuit substrate according to claim 1, wherein the conductive ink that covers the primer resin layer is coated so as to contact the entire surface of the wiring formation surface of the substrate.

4. The circuit substrate according to claim 1, wherein coloring of the primer resin layer is performed.

5. A manufacturing method of a circuit substrate comprising:
forming a primer resin layer having a predetermined adhesive force with respect to a substrate on a wiring formation surface of the substrate that has the wiring formation surface formed in a planar shape;
coating conductive ink so as to cover the primer resin layer, in which an adhesive force of the conductive ink with respect to the substrate is smaller than an adhesive force of the primer resin layer with respect to the substrate; and
removing a portion of the conductive ink which contacts the wiring formation surface of the substrate by a removing unit to form the wiring layer.

6. The manufacturing method of a circuit substrate according to claim 5, wherein as the removing unit, an adhesive roll that has an adhesive on an outer peripheral surface thereof and is rotatable in a shaft-rotation direction is used, and
wherein the adhesive roll is rotated and the adhesive rolls on the conductive ink so that a portion of the conductive ink which contacts the wiring formation surface of the substrate is removed.

7. The manufacturing method of a circuit substrate according to claim 5, wherein the conductive ink that covers the primer resin layers are coated so as to contact the entire surface of the wiring formation surface of the substrate.

8. The manufacturing method of a circuit substrate according to claim 5, wherein coloring of the primer resin layers is performed.
